(19) United States
(12) Patent Application Publication
(10) Pub. No.: US 2007/0293028 A1
(43) Pub. Date: Dec. 20, 2007

(54) Method of forming low forward voltage Shottky barrier diode with LOCOS structure therein

(75) Inventor: Shye-Lin Wu, Hsinchu Hsien (TW)

Correspondence Address: BIRCH STEWART KOLASCH & BIRCH, PO BOX 747, FALLS CHURCH, VA, 22040-0747, US

(73) Assignee: Chip Integration Tech.Co.,Ltd.

(21) Appl. No.: 11/453,799

(22) Filed: Jun. 16, 2006

(51) Int. Cl. H01L 21/28; H01L 21/44

(52) U.S. Cl. 438/570

(57) ABSTRACT

A method of forming a power Schottky rectifier device is disclosed. The Schottky rectifier device including LOCOS structure and two p doped layers formed thereunder to avoid premature of breakdown voltage. The Schottky rectifier device comprises: an n− drift layer formed on an n+ substrate; a cathode metal layer formed on a surface of the n+ substrate opposite the n− drift layer; a pair of field oxide regions and termination field oxide region formed into the n− drift layer and each spaced from each other by the mesas. A stack of metal layers formed of Ti/Ni/Ag are formed atop the front surface. A RTP (rapid thermal process) is then followed to form a Schottky barrier diode. Alternatively, the stack metal layers are formed of Ti/TiN/Al. Yet, the Al is formed after RTP. Subsequently, the top metal layer is patterned to form an anode electrode.

### FIELD OF THE INVENTION

The present invention relates to a semiconductor process, specifically, to a Schottky barrier power rectifier having LOCOS structure to prevent leakage current.

### BACKGROUND OF THE INVENTION

Schottky diode is an important power device and used extensively as output rectifiers in switching-mode power supplies and in other high-speed power switching applications, such as motor drives, switching of communication device, industry automation and electronic automation and so on. The power devices are usually required characteristics of carrying large forward current, high reverse-biased blocking voltage, such as above 100 volt, and minimizing the reverse-biased leakage current.

A number of power rectifiers have been used to provide high current and reverse blocking characteristics. An exemplary method to form a Schottky barrier diode is disclosed by Kanemaru et al in U.S. Pat. No. 6,483,164. the processes are shown in FIG. 1A to FIG. 1C. Referring to FIG. 1A, a semiconductor substrate having an n+ doped layer 10 and an n drift layer 20 extended to a first surface 20A is prepared. An oxide layer 25 is then formed on the first surface 20A. Afterward, referring to FIG. 1B, the oxide layer 25 is patterned to define positions of guard ring 35 at the termination region. Guard ring regions 35 doped with p-type impurities are then buried into n drift layer 20 by an ion implant with B+ impurities or diffusion using boron nitride as a source. Thereafter, a thermal oxidation is then performed to drive in the impurities. At the same time, an oxide layer 30 is grown on the first surface and thickened the oxide layer 25. Thereafter, a second photoresist pattern 40 having an opening to define an anode contact region is then coated on the resulted surface.

Referring to FIG. 1C, a wet etch is then performed to remove those exposed oxide layers 30, 25 by using the photoresist pattern 40 as a mask. Portions of p+ guard ring regions 35 and the n drift layer 20 in between are thus exposed. After a removal of photoresist pattern 40, a Schottky barrier metal layer 50 is then formed on the resulted surface. Thereafter, a third photoresist (not shown) and an etch steps are then performed to defied the Schottky barrier metal layer 50. After the layers formed on the backside surface during forgoing step are removed, a metal layer 60 is then formed, which is served as a cathode.

The conventional Schottky rectifier with guard rings 35 may require at least three photo masks. Thus, an object of the present method is to improve the breakdown voltage and simplify the processes. According to the present invention, only two photo masks are used.

### SUMMARY OF THE INVENTION

A power Schottky rectifier device and method of making the same are disclosed. The Schottky rectifier device including LOCOS structure and two p doped layers formed thereunder to avoid premature of breakdown voltage. The Schottky rectifier device comprises: an n− drift layer formed on an n+ substrate; a cathode metal layer formed on a surface of the n+ substrate opposite the n− drift layer; a pair of field oxide regions and termination field oxide region formed into the n− drift layer and each spaced from each other by the mesas.

In a first preferred embodiment, a stack of metal layers from a bottom thereof a Ti, Ni, and Ag is formed atop the surfaces of field oxide regions mesas, and the termination region. A RTP (rapid thermal process) is then followed to form a Schottky barrier diode. Subsequently, the top metal layer is patterned to form an anode electrode.

In a second preferred embodiment, a stack of metal layers from a bottom thereof a Ti, TiN is formed atop the surfaces of field oxide regions, mesas, and the termination region. A RTP (rapid thermal process) is then followed to form a Schottky barrier diode. Thereafter, an aluminum layer is then deposited on the Ti/TiN stack layer. Subsequently, the top metal layer is patterned to form an anode electrode.

The top metal layer of the Schottky barrier diode according to the first preferred embodiment is found to have excellent electrical performance such as low forward voltage and low reverse current. The electrical performance according to the second preferred embodiment is found to be even better than the device according to the first preferred embodiment.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A to 1C show steps of forming a conventional three-mask Schottky barrier diode with p+ guard ring structure at the termination in accordance with prior art.

FIG. 2 is a cross-sectional view of forming an oxide layer on an n− epi-layer and an n layer beneath the n− epi-layer of an n+ semiconductor substrate in accordance with the present invention.

FIG. 3 is a cross-sectional view of forming a nitride mask pattern layer on the oxide layer and forming a dual implant region into n− epi layer in accordance with the present invention.

FIG. 4 is a cross-sectional view of performing thermal oxidation to form LOCOS structure, and termination region, as well as to extend the dual p region in accordance with the present invention.

FIG. 5a is a cross-sectional view of forming a stack of metal layers of Ti/Ni/Ag, performing RTA, patterning the stack of metal layers to form anode electrode on the front surface and forming a cathode electrode on the back side surface of the substrate in accordance with a first preferred present invention. or

FIG. 5b is a cross-sectional view of forming a stack of metal layers of Ti/TiN, performing RTA, depositing Al layer, patterning the stack of metal layers to form anode electrode on the front surface, and forming a cathode electrode on the back side surface of the substrate in accordance with a second preferred present invention.

FIGS. 6A and 6B are a synoptic layouts to show the field oxide regions at the active regions and the termination region, only two masks are used.

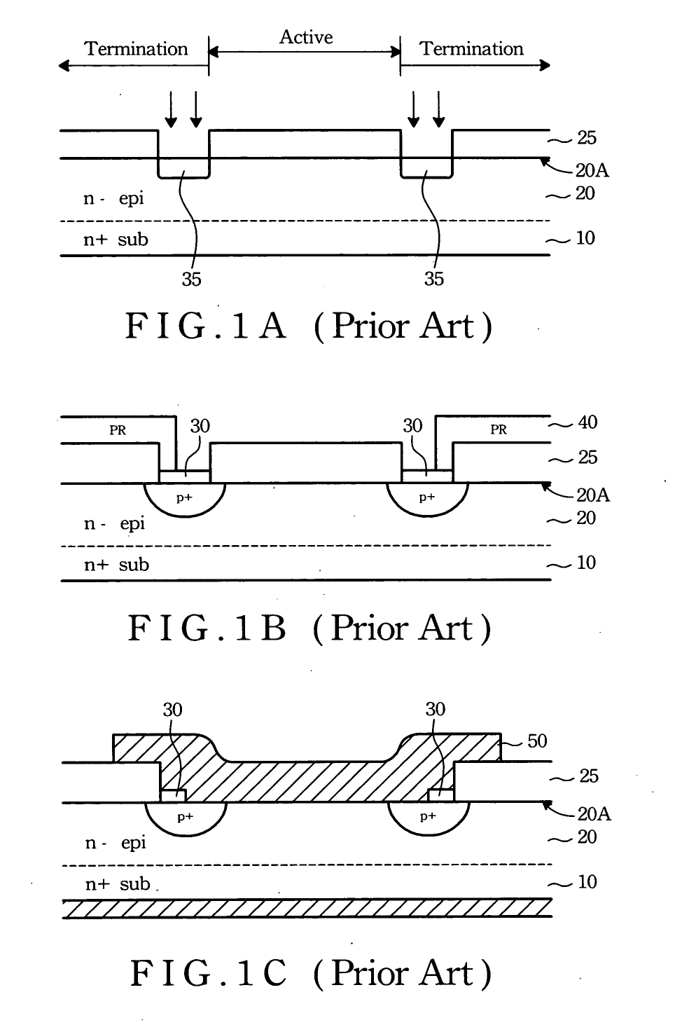

### DETAILED DESCRIPTION OF THE PREFERRED EMBODIMENT

As depicted in the forgoing background of the invention, the conventional technique requires at least three photo masks to form a power rectifier device and its termination structure. The present invention can simplify the processes and only two photo masks are used. The detailed descriptions are as follows:

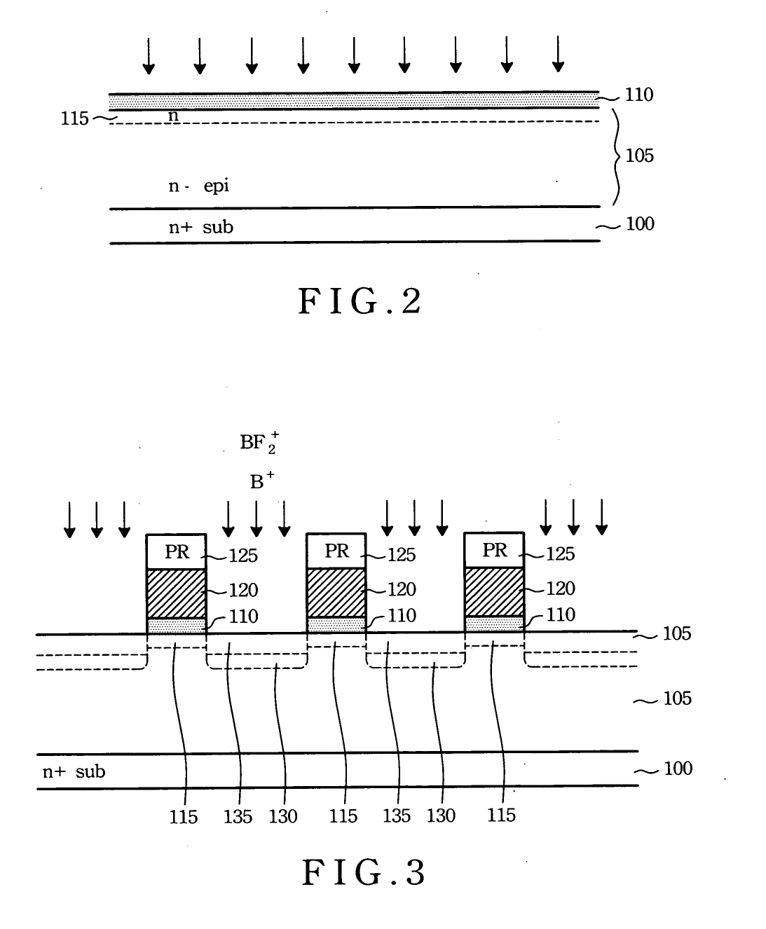

Referring to FIG. 2, a cross-sectional view, shows an n+ doped semiconductor substrate 100 formed with a drift layer thereon which is an n− epi-layer 105. An oxide layer 110 of about 5-50 nm in thickness grown on the n− epi-layer 105 is then followed.

Afterward, a blanket ion implantation by implanting n-type ion species into n− epi layer 105 to form an n layer 115 beneath the oxide layer 110 is then carried out. The dosage and implant energy are, respectively, from 0 (without implant) to 5×10¹³/cm² and 10-200 keV for phosphorus ion implant. Hence, the impurity concentration in n layer 115 is higher than that of in the n− epi layer 105 but still lower than that of in the n+ doped semiconductor substrate 100.

To define active region, referring to FIG. 3, a nitride layer 120 is formed on the oxide layer 110. A photoresist pattern 125 coated on the nitride layer 120 to define an active region is then followed. Subsequently, an etching back step is performed to etch the nitride layer 120 and the oxide layer 110 by using the photoresist pattern 125 as a mask.

Still referring to FIG. 3, a dual implant process implants B⁺ and BF₂⁺ into the n− epi layer 105 to form a p− region 130 and a p region 135 in different depths is then successively performed. The dosage and the implant energy are about 5×10¹¹-5×10¹⁴/cm² and 10-200 keV for boron ions and about 5×10¹²-5×10¹⁵/cm² and 30-200 keV for BF₂⁺ ions.

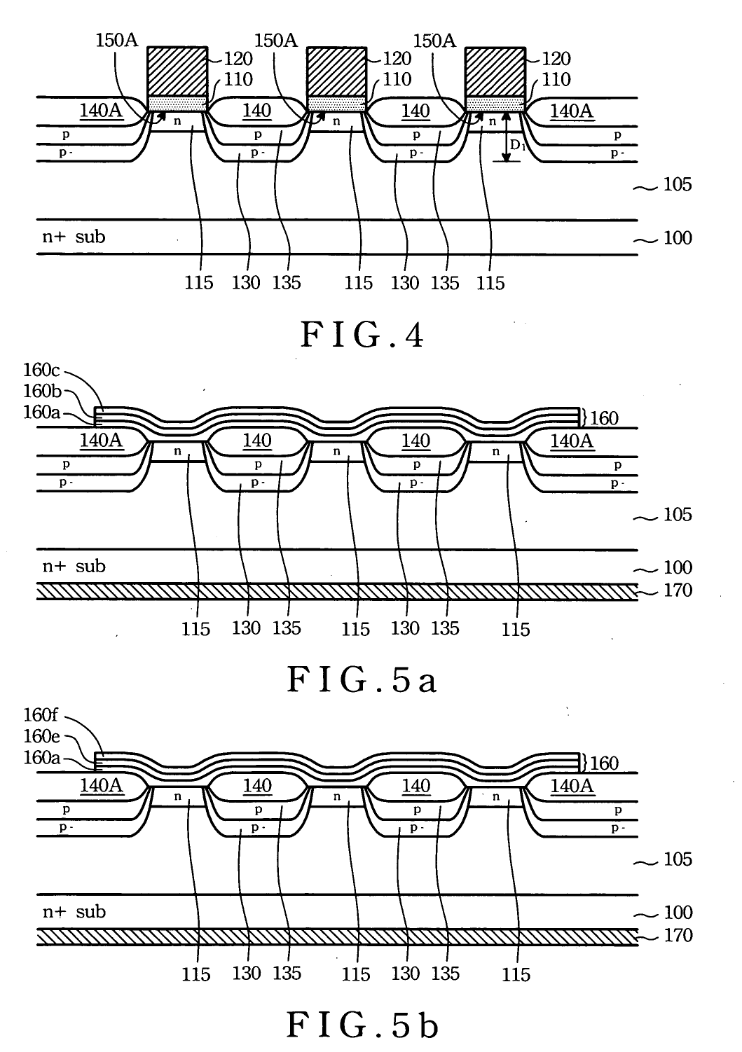

After ion implantation, the photoresist pattern 125 is stripped away and a thermal oxidation process is followed by using the nitride layer 120 as a mask, as is shown in FIG. 4. During the thermal oxidation process, a pair of thick field oxide regions 140 grown into the active region of the substrate and thick oxide termination regions 140A grown into the perimeter of the substrate are formed by using the nitride layer 120 as a mask. In addition, the ions in the p− region 130, p region 135, and n layer 125 are driven in both lateral and longitudinal into n− epi layer 105 and results in extending the regions thereof.

In a preferred embodiment, the width of the mesa region 150A in between two field oxide regions 140 and in between the field oxide region 140 and termination is between about 3-30 μm for field oxide region having 0.3-2 μm in thickness and the p/n junction 130/105 having a depth D1 of about 0.3-3 μm from the surface of the mesa region 150A.

Referring to FIG. 5a, the nitride layer 120 and the pad oxide layer 110 are removed firstly. A top metal layer 160 deposited on the front surface is then followed. The top metal layer 160 is a stack of layers of Ti 160a/Ni 160b/Ag 160c having a thickness between about 5 nm to 500 nm for a Ti layer 160a and Ni layer 160b, and between about 300 nm to 10 μm for Ag 160c. After that a RTP (rapid thermal process) at a temperature between about 450° C. to 950° C. is performed for 1 second to 300 seconds.

Subsequently, the top metal layer 160 served as anode is patterned to define the extension portions on the termination regions 140A. A backside layer milling by a chemical/mechanical polish process is then followed to remove all of the layers during aforementioned processes formed thereon. Preferably, the milling step also removes a portion thickness of the n+ substrate 100. Thereafter, a metal layer 170 is formed on the milled surface to function as a cathode electrode.

According the experiments by the inventor, for a chip size of about 50 mil×50 mil, to load three Ampere of current I_{F} at a forward voltage V_{F} from a value of 0.7V for a Schottky diode formed by conventional method can be down to 0.48V for a Schottky diode formed according to the present invention. Another benefit of the present invention gained is the extreme low leakage current at a reverse bias. For instance, for the chip size of aforementioned, the reverse current I_{R} at is about 200 μA vs. 100 μA, respectively, for conventional diode and the present invention.

In another preferred embodiment, the stack of metal layers 160 is formed of Ti 160a/TiN 160e/Al 160f, as is shown in FIG. 5b. The RTP anneal, however, is prior to deposit an aluminum layer 160c. The stack having a thickness between about 5 nm to 500 nm for a Ti layer 160a and TiN layer 160e, and between about 300 nm to 10 μm. The RTP (rapid thermal process) is performed at a temperature between about 450° C. to 950° C. for 1 second to 300 seconds. The Al layer 160c has a thickness between about 1 μm to 10 μm.

Subsequently, the top metal layer 160 served as anode is patterned to define the extension portions on the termination regions 140A. A backside layer milling by a chemical/mechanical polish process is then followed to remove all of the layers during aforementioned processes formed thereon. Preferably, the milling step also removes a portion thickness of the n+ substrate 100. Thereafter, a metal layer 170 is formed on the milled surface to function as a cathode electrode.

The electrical performance of Schottky diode formed according to the second preferred embodiment of the present invention is found to be better than the first performed embodiment. For example, for loading the same forward current, the VF is found to be further reduced.

The technique of a RTP anneal after top metal formed of Ti 160a/Ni 160b/Ag 160c according to the first preferred embodiment or of forming Ti 160a/TiN 160b then performing a RTP anneal then deposited Al 160c can also be applied to power MOSFET or Bipolar transistor or Zener diode formation to get low forward voltage

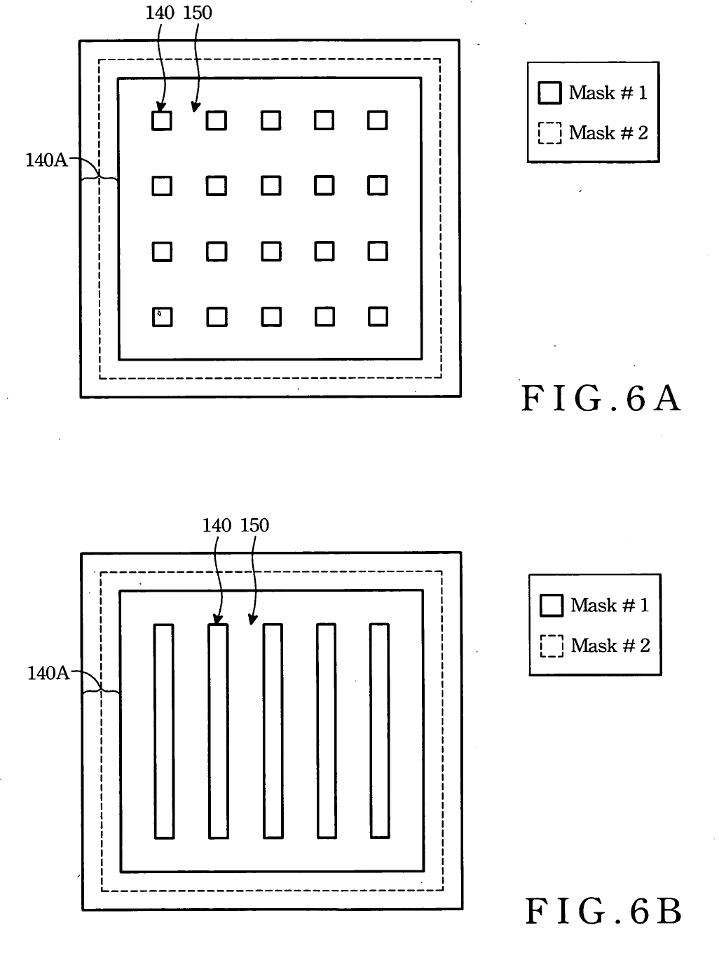

FIG. 6A shows a synoptic layout of the devices in accordance with the present invention. It shows more field oxide regions at the oxide regions than forgoing cross-sectional view. Other than the field oxidation regions distributed in a form of dots in a matrix, they can be distributed in a form of long strips in parallel, as is shown in FIG. 6B. Only two photo masks are required to form high performance Schottky barrier diode—one is to define the active region, the other one is to define the anode metal. The field oxide regions 140 in the active region, however, can serves as a buffer layer for stress relief while bonding on the top surface.

The benefits of this invention are:
(1) The processes provided are much simpler than the conventional methods. The method according to the present invention demands only two photo masks: one is to define the active region and the other is for top metal electrode definition.
(2) The field oxide regions in the active region of the substrate can serve as a buffer layer for stress relief during the bonding process. In addition, the field oxide regions 140 can also improve the breakdown voltage.
(3) The termination field oxide regions 140A are broad and flatted and thus the bending regions of the depletion boundary are anticipated to be far away from the active region than the conventional device.
(4) The forward current is almost composed of majority carriers and thus the switching speed of the device is superior to those of the conventional devices.

As is understood by a person skilled in the art, the foregoing preferred embodiment of the present invention is an illustration of the present invention rather than limiting thereon. It is intended to cover various modifications and similar arrangements included within the spirit and scope of the appended claims, the scope of which should be accorded the broadest interpretation so as to encompass all such modifications and similar structure.

What is claimed is:

1. A method of forming semiconductor device, said method comprising the steps of:
providing a first conductive type semiconductor substrate having an epi-layer doped with impurities of said first conductive type formed thereon;
forming a first oxide layer on said epi-layer;
forming a nitride layer on said oxide layer;
patterning said nitride layer and said first oxide layer to define an active region and a termination region;
performing ion implant to form a first doping layer of a second conductive type by using said patterned nitride layer and said first oxide layer pattern layer as an implant mask;
performing a thermal oxidation to form a plurality of field oxide regions into said active region and said termination region by using said patterned nitride layer and said first oxide layer as an oxidation mask;
removing said nitride layer and said oxide layer to expose said epi-layer;
forming a top metal layer on said epi-layer, said field oxide regions and said termination region;
performing a rapid thermal process;
patterning said top metal layer to define an anode electrode;
removing layers formed on a backside surface of said semiconductor substrate during forgoing steps; and
forming a backside metal layer on said backside surface, said backside metal layer acted as a cathode electrode.

2. The method according to claim 1 and further comprising a step of performing ion implant to form a second doping layer beneath said first oxide layer before the step of forming hard mask pattern layer.

3. The method according to claim 2 wherein said second doping layer has impurity concentration higher than that of said epi-layer but lower than that of semiconductor substrate.

4. The method according to claim 1 wherein said first doping layer is formed by implanting both B⁺ and BF₂⁺ ion species into different depths so that a p doping layer and a p− doping layer are formed when performing said step of thermal oxidation, wherein said p doping layer is positioned above said p− doping and has higher impurity concentration than said p− doping layer.

5. The method according to claim 1 wherein said top metal layer is formed of stacked layers of Ti/Ni/Ag.

6. The method according to claim 1 wherein said top metal layer is formed of stacked layers of Ti/TiN.

7. The method according to claim 1 after step of forming top metal layer and before patterning said top metal layer to define an anode electrode further comprising forming Al layer atop said top metal layer.

8. The method according to claim 1 wherein said RTP (rapid thermal process) is performed at a temperature between about 450° C. to 950° C. for 1 s to 300 s.

9. A method of forming semiconductor device, said method comprising the steps of:
providing a first conductive type semiconductor substrate having an epi-layer doped with impurities of said first conductive type formed thereon;
forming a first oxide layer on said epi-layer;
forming a nitride layer on said oxide layer;
patterning said nitride layer and said first oxide layer to define an active region and a termination region;
performing ion implant to form a first doping layer of a second conductive type by using said patterned nitride layer and said first oxide layer pattern layer as an implant mask;
performing a thermal oxidation to form a plurality of field oxide regions into said active region and said termination region by using said patterned nitride layer and said first oxide layer as an oxidation mask;
removing said nitride layer and said oxide layer to expose said epi-layer;
forming a stack layers from a bottom thereof. Ti, Ni, and Ag on a surface of said epi-layer, said field oxide regions and said termination region;
performing a rapid thermal process;
patterning said top metal layer to define an anode electrode;
removing layers formed on a backside surface of said semiconductor substrate during forgoing steps; and
forming a backside metal layer on said backside surface, said backside metal layer acted as a cathode electrode.

10. The method according to claim 9 wherein said RTP (rapid thermal process) is performed at a temperature between about 450° C. to 950° C. for 1 s to 300 s.

11. A method of forming semiconductor device, said method comprising the steps of:
providing a first conductive type semiconductor substrate having an epi-layer doped with impurities of said first conductive type formed thereon;
forming a first oxide layer on said epi-layer;
forming a nitride layer on said oxide layer;
patterning said nitride layer and said first oxide layer to define an active region and a termination region;
performing ion implant to form a first doping layer of a second conductive type by using said patterned nitride layer and said first oxide layer pattern layer as an implant mask;
performing a thermal oxidation to form a plurality of field oxide regions into said active region and said termination region by using said patterned nitride layer and said first oxide layer as an oxidation mask;
removing said nitride layer and said oxide layer to expose said epi-layer;
forming a stack layers from a bottom thereof. Ti, TiN on a surface of said epi-layer, said field oxide regions and said termination region;
performing a rapid thermal process;
forming an Al layer on said stack layers;
patterning said top metal layer to define an anode electrode;
removing layers formed on a backside surface of said semiconductor substrate during forgoing steps; and
forming a backside metal layer on said backside surface, said backside metal layer acted as a cathode electrode.

12. The method according to claim 11 wherein said RTP (rapid thermal process) is performed at a temperature between about 450° C. to 950° C. for 1 s to 300 s.
